(19) United States
(12) Patent Application Publication
(10) Pub. No.: US 2024/0332000 A1
(43) Pub. Date: Oct. 3, 2024

(54) DOPED SILICON-CONTAINING MATERIALS WITH INCREASED ELECTRICAL, MECHANICAL, AND ETCH CHARACTERISTICS

(71) Applicant: Applied Materials, Inc., Santa Clara, CA (US)

(72) Inventors: Akhil Singhal, Portland, OR (US); Deenesh Padhi, Saratoga, CA (US); Sukrant Dhawan, Santa Clara, CA (US); Vinayak Vats, San Ramon, CA (US)

(73) Assignee: Applied Materials, Inc., Santa Clara, CA (US)

(21) Appl. No.: 18/192,573

(22) Filed: Mar. 29, 2023

(51) Int. Cl. H01L 21/02; C23C 16/40; C23C 16/50; C23C 16/56

(52) U.S. Cl. CPC H01L 21/02129; C23C 16/401; C23C 16/50; C23C 16/56; H01L 21/02216; H01L 21/02274; H01L 21/02318; H01L 21/02576

(57) ABSTRACT

Exemplary methods of semiconductor processing may include providing deposition precursors to a processing region of a semiconductor processing chamber. A substrate may be disposed within the processing region. The deposition precursors may include a silicon-containing precursor. The methods may include providing a dopant precursor to the processing region of the semiconductor processing chamber. The dopant precursor may include a phosphorous-containing precursor. The methods may include generating plasma effluents of the deposition precursors and the dopant precursor. The methods may include depositing a silicon-containing material on the substrate. The silicon-containing material may be characterized by a stress of greater than or about −50 MPa.

### TECHNICAL FIELD

The present technology relates to methods of semiconductor processing. More specifically, the present technology relates to methods for producing doped silicon-containing materials for semiconductor structures.

### BACKGROUND

Integrated circuits are made possible by processes which produce intricately patterned material layers on substrate surfaces. Producing patterned material on a substrate requires controlled methods for forming and removing material. As device sizes continue to reduce, aspect ratios of structures and/or layers of materials may grow, and maintaining dimensions of these structures and properties of these layers of materials may be challenged. Developing silicon-containing materials, for example, that may have desirable electrical and mechanical characteristics may be a challenge. Additionally, as the number of material layers being patterned or removed during processing is expanding, producing materials that may have improved removal rates and/or removal selectivity to other exposed materials is becoming a greater challenge.

Thus, there is a need for improved systems and methods that can be used to produce high quality devices and structures. These and other needs are addressed by the present technology.

### SUMMARY

Exemplary methods of semiconductor processing may include providing deposition precursors to a processing region of a semiconductor processing chamber. A substrate may be disposed within the processing region. The deposition precursors may include a silicon-containing precursor. The methods may include providing a dopant precursor to the processing region of the semiconductor processing chamber. The dopant precursor may include a phosphorous-containing precursor. The methods may include generating plasma effluents of the deposition precursors and the dopant precursor. The methods may include depositing a silicon-containing material on the substrate. The silicon-containing material may be characterized by a stress of greater than or about −50 MPa.

In some embodiments, the silicon-containing precursor may be or include tetracthyl orthosilicate (TEOS). The deposition precursors may further include an oxygen-containing precursor. The oxygen-containing precursor may be or include nitrous oxide (N₂O). The plasma effluents of the deposition precursors and the dopant precursor may be generated at a plasma power less than or about 2000 W. The silicon-containing material may be characterized by a leakage current of less than or about 5.0 E-08 A/cm² at 9 MV/cm. The silicon-containing material may be characterized by a breakdown voltage of greater than or about 6.0 MV/cm at 0.001 A/cm². The silicon-containing material may be characterized by a wet etch rate ratio (WERR) of greater than or about 2.0. The methods may include annealing the silicon-containing material. Annealing the silicon-containing material may include exposing the silicon-containing material to a temperature of greater than or about 600° C.

Embodiments of the present technology may encompass semiconductor processing method. The methods may include providing a silicon-containing precursor and an oxygen-containing precursor to a processing region of a semiconductor processing chamber. A substrate may be disposed within the processing region. The methods may include providing a dopant precursor to the processing region of the semiconductor processing chamber. The dopant precursor may include a phosphorous-containing precursor. The methods may include generating plasma effluents of the silicon-containing precursor, the oxygen-containing precursor, and the dopant precursor. The methods may include depositing a silicon-containing material on the substrate. The silicon-containing material may be characterized by a stress of greater than or about −50 MPa. The silicon-containing material may be characterized by a wet etch rate ratio (WERR) of greater than or about 2.0.

In some embodiments, the dopant precursor may be or include phosphine (PH₃). A flow rate of the dopant precursor may be less than or about 500 sccm. The silicon-containing material may be characterized by a phosphorous content of less than or about 5 at. %. The silicon-containing material may be deposited on a polysilicon material. The methods may include annealing the silicon-containing material at a temperature of greater than or about 600° C. for greater than or about 5 minutes. Subsequent annealing, a phosphorous content in the silicon-containing material may decrease by less than or about 1.0 at. %.

Embodiments of the present technology may encompass semiconductor processing method. The methods may include providing deposition precursors to a processing region of a semiconductor processing chamber. A substrate may be disposed within the processing region. The methods may include providing a dopant precursor to the processing region of the semiconductor processing chamber. The dopant precursor may include a phosphorous-containing precursor. The methods may include generating plasma effluents of the deposition precursors and the dopant precursor. The methods may include depositing a silicon-containing material on the substrate. The silicon-containing material may be characterized by a phosphorus content of less than or about 3 at. %. The silicon-containing material may be characterized by a stress of greater than or about −50 MPa. The silicon-containing material may be characterized by a wet etch rate ratio (WERR) of greater than or about 2.0.

In some embodiments, the silicon-containing material may include phosphorous doped silicon oxide. The silicon-containing material may be characterized by a leakage current of less than or about 1.0 E-09 A/cm². The silicon-containing material may be characterized by a breakdown voltage of greater than or about 6.0 MV/cm at 0.001 A/cm².

Such technology may provide numerous benefits over conventional systems and techniques. For example, embodiments of the present technology may produce silicon-containing materials, such as silicon-and-oxygen-containing materials, characterized by an increased wet etch rate ratio (WERR) and by compressive stress. Additionally, the present technology may produce silicon-containing materials with tunable film characteristics having increased electrical and mechanical properties. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3B show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size in order to scale devices. As structures are brought closer together within a device and material layers are made smaller, silicon-containing materials may be incapable of maintaining desirable electrical, mechanical, and etch characteristics. For example, as silicon-containing materials are made more compressive, a wet etch rate ratio (WERR) may suffer, which may lead to issues during etch operations, such as memory hole formation in 3D NAND applications. Additionally, as material layers are made smaller, silicon-containing materials may suffer from reduced electrical capabilities, such as increased leakage current and/or reduced breakdown voltages. Additionally, for these silicon-containing materials to be incorporated in semiconductor integration, processing may include a back-end-of-line anneal process that may expose structures to temperatures exceeding 600° C. or more. Many materials, including silicon-containing materials, may be impacted by this anneal, which can cause flaking that may be caused by poor adhesion.

The present technology overcomes these issues by performing a silicon-containing material deposition with a dopant precursor being provided with the deposition precursors. The dopant precursor, such as a phosphorous-containing precursor, may provide silicon-containing materials with desirable electrical, mechanical, and etch characteristics. For example, the incorporation of a dopant in the silicon-containing materials may break the tradeoff between stress and WERR. Additionally, the incorporation of a dopant in the silicon-containing material may provide silicon-containing materials characterized by low leakage current and high breakdown voltage while maintaining a low level of film defects during deposition and/or subsequent processing.

Although the remaining disclosure will routinely identify specific deposition processes utilizing the disclosed technology, and will describe one type of semiconductor processing chamber, it will be readily understood that the processes described may be performed in any number of semiconductor processing chambers, as well as for any number of processing operations in which films as described may be incorporated. Accordingly, the technology should not be considered to be so limited as for use with these specific deposition processes or chambers alone. The disclosure will discuss one possible chamber that may be used to perform processes according to embodiments of the present technology before methods of semiconductor processing according to the present technology are described.

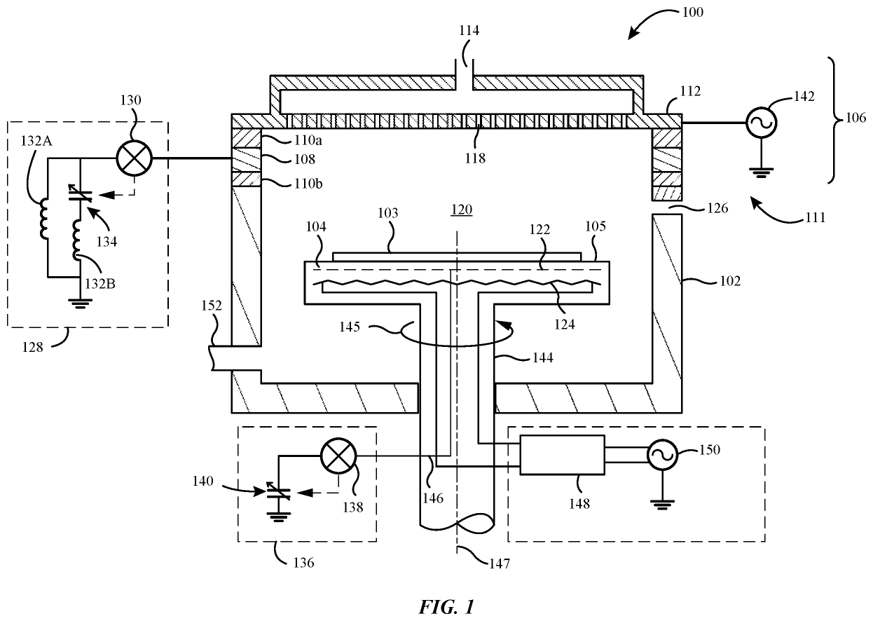

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

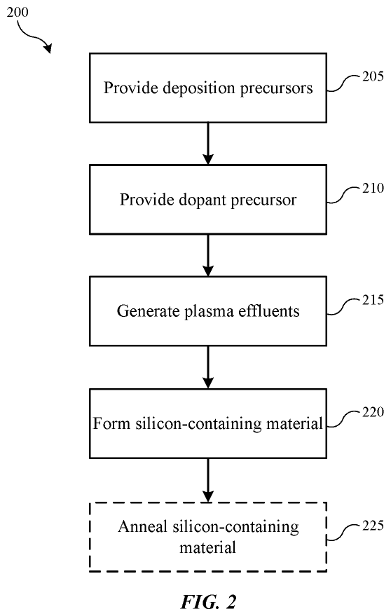

FIG. 2 shows exemplary operations in a processing method 200 according to some embodiments of the present technology. The method 200 may be performed in a variety of processing chambers, including processing chamber 100 described above, as well as any other in which the operations may be performed. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

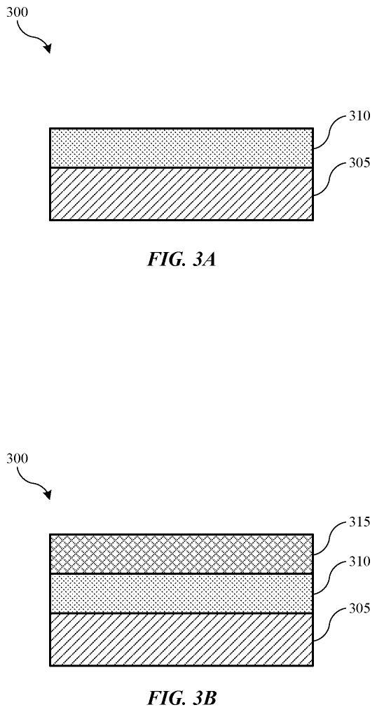

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above. Method 200 describes operations shown schematically in FIGS. 3A-3B, the illustrations of which will be described in conjunction with the operations of method 200. It is to be understood that FIGS. 3A-3B illustrate only partial schematic views of an exemplary structure 300, and a substrate 305 may contain any number of additional materials and features having a variety of characteristics and aspects as illustrated in the figures.

At operation 205, one or more deposition precursors may be delivered to the processing region of the semiconductor processing chamber. As shown in FIG. 3A, for example, the material being deposited may be a silicon-containing material 315 used in semiconductor processing. In embodiments, the silicon-containing material 315 may be deposited on another material 310, such as a polysilicon material or a silicon-and-nitrogen-containing material in a 3D NAND application. The deposition precursors may include any number of precursors, including a silicon-containing precursor and an oxygen-containing precursor, and any other deposition precursors useful in silicon-containing material formation. The deposition precursors may be flowed together or separately. For example, in exemplary embodiments in which a silicon-and-oxygen-containing material may be formed, a silicon-containing precursor and an oxygen-containing precursor may be delivered to the processing region of the processing chamber. As discussed below, plasma enhanced deposition may be performed in some embodiments of the present technology, which may facilitate material reactions and deposition.

In embodiments, the silicon-containing precursor may be or include one or more of silane and disilane, among other silicon-containing precursors useful in semiconductor processing. For example, the silicon-containing precursor may be a silicon-and-oxygen-containing precursor such as tetraethyl orthosilicate (TEOS), octamethylcyclotetrasiloxane (OMCTS), or any other silicon-containing precursor useful in semiconductor processing. The oxygen containing precursor may be or include molecular oxygen (O₂), ozone (O₃), nitrous oxide (N₂O), or any other oxygen-containing precursor useful in semiconductor processing.

The present technology may include additionally providing a dopant precursor at operation 210. The dopant precursor may be provided with the other deposition precursors, such as the silicon-containing precursor and/or the oxygen-containing precursor. In embodiments, the dopant precursor may be a phosphorous-containing precursor, which may facilitate phosphorus incorporation in the deposited silicon-containing material 315. The phosphorous-containing precursor may be or include one or more of phosphine (PH₃), diphosphine (P₂H₆), tricthylorthophosphate (TEPO), trimethyl phosphate (TMP), tricthyl phosphate (TEP), tributyl phosphate (TBP), or any other phosphorous-containing precursor useful in semiconductor processing.

Depending on the deposition precursors, a flow rate of the dopant precursor may be adjusted to control dopant incorporation in the deposited silicon-containing material 315. For example, in the case of a phosphorous dopant, while the flow rates of the other deposition precursors may be greater than hundreds of mg/min or sccm, the dopant precursor may be flowed at a flow rate less than or about 1000 sccm, and may be delivered at a flow rate less than or about 900 sccm, less than or about 800 sccm, less than or about 700 sccm, less than or about 600 sccm, less than or about 500 sccm, less than or about 400 sccm, less than or about 350 sccm, less than or about 300 sccm, less than or about 250 sccm, less than or about 200 sccm, less than or about 150 sccm, less than or about 100 sccm, or less.

In additional embodiments, a carrier gas may be combined with the deposition precursors and/or the dopant precursor flowing into the processing region of the semiconductor processing chamber. In embodiments, the carrier gas may be one or more of helium, argon, and molecular nitrogen (N₂), among other carrier gases. In embodiments, a flow rate for the carrier gas may be greater than or about 1000 sccm, greater than or about 1500 sccm, greater than or about 2000 sccm, greater than or about 2500 sccm, greater than or about 3000 sccm, greater than or about 4000 sccm, greater than or about 5000 sccm, greater than or about 6000 sccm, or more. For some embodiments, increasing carrier gas flow rate may benefit the mechanical properties of the film. Additionally, the presence of a carrier gas can also make it easier to strike a plasma.

The precursors delivered may all be used to form a plasma within the processing region of the semiconductor processing chamber at operation 215. The plasma be generated by providing RF power to the gas distributor or the pedestal to generate a plasma within processing region, although any other processing chamber capable of producing plasma may similarly be used. The plasma may be generated at less than or about 2000 W, and may be generated at less than or about 1750 W, less than or about 1500 W, less than or about 1250 W, less than or about 1000 W, less than or about 800 W, less than or about 600 W, less than or about 400 W, or less.

During operation 215 of method 200, an additional power source, a bias power source, may be engaged and coupled with the pedestal as previously described to provide a bias to the plasma generated above the substrate 305. This may draw plasma effluents to the substrate 305. The bias power applied may be relatively low to limit damage to the structure 300. Accordingly, in some embodiments a plasma power source may deliver a plasma power to the pedestal of less than or about 1000 W, and may deliver a power of less than or about 900 W, less than or about 800 W, less than or about 700 W, less than or about 600 W, less than or about 500 W, less than or about 400 W, less than or about 300 W, less than or about 200 W, or less. Additionally, by adjusting the source power and the bias power applied, densification of the deposited silicon-containing material 315 may occur during the method 200. Without being bound by any particular theory, higher plasma power may increase dopant incorporation may increase as dopant and hydrogen bond energy, such as between phosphorous and hydrogen, may be lower compared to the bond energy between silicon and hydrogen.

As shown in FIG. 3B, at operation 220, the silicon-containing material 315 may be deposited on the substrate 305, such as on the material 310, that includes the dopant within the deposited silicon-containing material 315. For example, the silicon-containing material 315 may be a phosphorous doped silicon oxide. By incorporating the dopant-containing precursor in some embodiments, stress may be controlled within the film, while producing a film with reduced leakage current and increased breakdown voltage. The silicon-containing material 315 may be useful in 3D NAND applications, especially in 3D NAND applications with increased tiers of silicon oxide and polysilicon layering. Specifically, increased tiers in 3D NAND demands a silicon oxide with a high etch rate to assist in the formation of straighter memory holes during etch operations. Depending on the structure 300, a thickness of the silicon-containing material 315 may be less than or about 30 nm, and the thickness of the silicon-containing material 315 may be less than or about 28 nm, less than or about 26 nm, less than or about 24 nm, less than or about 22 nm, less than or about 20 nm, less than or about 18 nm, less than or about 16 nm, or less.

Because of the reaction being performed in some embodiments, the semiconductor processing chamber, the pedestal, or the substrate 305 may be maintained at a temperature greater than or about 250° C., and in some embodiments may be maintained at a temperature that is greater than or about 300° C., greater than or about 320° C., greater than or about 340° C., greater than or about 360° C., greater than or about 380° C., greater than or about 400° C., greater than or about 420° C., greater than or about 440° C., greater than or about 460° C., greater than or about 480° C., greater than or about 500° C., greater than or about 520° C., greater than or about 540° C., greater than or about 560° C., greater than or about 580° C., greater than or about 600° C. greater than or about 620° C., greater than or about 640° C., or more. By increasing the temperature, the deposition rate of the material may be reduced. Conversely, by decreasing the temperature, the deposition rate of the material may be increased. Accordingly, in some embodiments, the semiconductor processing chamber, the pedestal, or the substrate 305 may be maintained at a temperature less than or about 700° C., and in some embodiments may be maintained at a temperature that is less than or about 680° C., less than or about 660° C., less than or about 640° C., less than or about 620° C., less than or about 600° C., less than or about 580° C., less than or about 560° C., less than or about 540° C., less than or about 520° C., or less.

The semiconductor processing chamber may be maintained at a pressure greater than or about 500 mTorr, and in some embodiments may be maintained at a pressure that is greater than or about 600 mTorr, greater than or about 700 mTorr, greater than or about 800 mTorr, greater than or about 900 mTorr, greater than or about 1 Torr, greater than or about 2 Torr, greater than or about 3 Torr, greater than or about 4 Torr, greater than or about 5 Torr, greater than or about 6 Torr, greater than or about 7 Torr, greater than or about 8 Torr, greater than or about 9 Torr, greater than or about 10 Torr, greater than or about 11 Torr, greater than or about 12 Torr, greater than or about 13 Torr, greater than or about 14 Torr, greater than or about 15 Torr, or more. Similarly, in some embodiments, the semiconductor processing chamber may be maintained at a pressure less than or about 30 Torr, and in some embodiments may be maintained at a pressure that is less than or about 28 Torr, less than or about 26 Torr, less than or about 24 Torr, less than or about 22 Torr, less than or about 20 Torr, less than or about 15 Torr, less than or about 10 Torr, less than or about 8 Torr, less than or about 6 Torr, or less. At higher pressure, deposition rate may be increased, and, at higher pressure, deposition rate may be decreased.

The dopant may be included in any amount or concentration, and may be included at less than or about 5 at. % in the deposited silicon-containing material 315, and in some embodiments may be included at less than or about 4.8 at. %, less than or about 4.6 at. %, less than or about 4.4 at. %, less than or about 4.2 at. %, less than or about 4 at. %, less than or about 3.8 at. %, less than or about 3.6 at. %, less than or about 3.4 at. %, less than or about 3.2 at. %, less than or about 3 at. %, less than or about 2.8 at. %, less than or about 2.6 at. %, less than or about 2.4 at. %, less than or about 2.2 at. %, less than or about 2 at. %, less than or about 1.8 at. %, less than or about 1.6 at. %, less than or about 1.4 at. %, less than or about 1.2 at. %, less than or about 1 at. %, or less.

The silicon-containing material 315 may be deposited with high compressive stress. Unlike low stress materials that may characterized by internal stress levels that are closer to neutral stress (i.e., 0 MPa), high stress materials are characterized by internal stress levels that are significantly greater than 0 MPa (i.e., high positive (tensile) stress) or significantly less than 0 MPa (i.e., high negative (compressive) stress). High positive stress, which may be characterized as tensile stress, may result in the expansion of adjacent material that may create an outward, pushing force on adjacent substrate features. High negative stress, which may be characterized as compressive stress, may result in the contraction of adjacent material that may create an inward, pulling force on adjacent substrate features. In other words, higher-stress materials may be characterized by a stress level with an absolute value that is significantly greater than 0 MPa. Thus, when a material is characterized by a stress level of “greater than −1000 MPa”, this refers to the absolute value of the stress level, and includes levels such as −1500 MPa, −2000 MPa, etc. Similarly, when a material is characterized by a stress level of “less than −1000 MPa”, this refers stress levels that are closer to neutral stress (i.e., 0 MPa), and includes levels such as-500 MPa, −100 MPa, etc., but does not extend to positive values greater than or about 1000 MPa.

Exemplary stress values of the silicon-containing material 315 may include greater than or about −50 MPa or more, where a stress value that is more negative means the material has more stress, and a stress value closer to 0 MPa has less stress. Additional exemplary stress value ranges may include greater than or about −60 MPa, greater than or about −70 MPa, greater than or about −80 MPa, greater than or about −90 MPa, greater than or about −100 MPa, greater than or about −110 MPa, greater than or about −120 MPa, greater than or about −130 MPa, greater than or about −140 MPa, greater than or about −150 MPa, or more. By doping the silicon-containing material 315, a tradeoff between stress and wet etch rate ratio (WERR) may be achieved. More specifically, compared to conventional silicon-containing materials characterized by increased WERR, such as undoped silicon-and-oxygen-containing materials, the silicon-containing materials including a phosphorous dopant according to the present technology may be characterized by high compressive stress. Additionally, unlike tensile silicon-containing materials, the compressive silicon-containing materials of the present technology may experience increased adhesion and reduced flaking.

The silicon-containing material 315 may be characterized by a WERR of greater than or about 2.0, and may be characterized by a WERR of greater than or about 2.1, greater than or about 2.2, greater than or about 2.3, greater than or about 2.4, greater than or about 2.5, greater than or about 2.6, greater than or about 2.7, greater than or about 2.8, greater than or about 2.9, greater than or about 3.0, greater than or about 3.1, greater than or about 3.2, or more. The incorporation of the dopant may increase the WERR while also increasing the compressive stress of the silicon-containing material 315. The increased WERR may be attributed to the reduced bond energy between the dopant and oxygen compared to silicon and oxygen. For example, when the dopant includes phosphorous, the bond energy between phosphorous and oxygen is 335 KJ/mol, whereas the bond energy between silicon and oxygen is 452 KJ/mol.

Leakage current and dielectric breakdown may be impacted by the atomic concentrations within the materials produced. However, by producing materials according to embodiments of the present technology, leakage current at 9 MV/cm may be maintained at less than or about 5.0 E-8 A/cm², and may be maintained at less than or about 4.0 E-8 A/cm², less than or about 3.0 E-8 A/cm², less than or about 2.8 E-8 A/cm², less than or about 2.6 E-8 A/cm², less than or about 2.4 E-8 A/cm², less than or about 2.2 E-8 A/cm², less than or about 2.0 E-8 A/cm², less than or about 1.8 E-8 A/cm², or less. Additionally, breakdown voltage of the film at 0.001 A/cm² may be maintained at greater than or about 6.0 MV/cm, and may be maintained at greater than or about 6.5 MV/cm, greater than or about 7.0 MV/cm, greater than or about 7.5 MV/cm, greater than or about 8.0 MV/cm, greater than or about 8.5 MV/cm, greater than or about 9.0 MV/cm, greater than or about 9.5 MV/cm, greater than or about 10.0 MV/cm, greater than or about 10.5 MV/cm, greater than or about 11.0 MV/cm, greater than or about 11.5 MV/cm, greater than or about 12.0 MV/cm, greater than or about 12.5 MV/cm, greater than or about 13.0 MV/cm, greater than or about 13.5 MV/cm, greater than or about 14.0 MV/cm, or higher.

At optional operation 225, the method 200 may include annealing the substrate 305. While the deposition may be performed at a first temperature, the thermal anneal may be performed at a second temperature greater than the first. For example, the thermal anneal may be performed at a temperature greater than or about 480° C., and the thermal anneal may be performed at greater than or about 500° C., greater than or about 510° C., greater than or about 520° C., greater than or about 530° C., greater than or about 540° C., greater than or about 550° C., greater than or about 560° C., greater than or about 570° C., greater than or about 580° C., greater than or about 590° C., greater than or about 600° C., greater than or about 650° C., greater than or about 700° C., greater than or about 750° C., greater than or about 800° C., greater than or about 850° C., or higher. The thermal anneal may be performed for a period of time that may be greater than or about 0.5 minutes, and may be greater than or about 1 minute, greater than or about 2 minutes, greater than or about 3 minutes, greater than or about 4 minutes, greater than or about 5 minutes, greater than or about 6 minutes, greater than or about 8 minutes, greater than or about 10 minutes, or more. During the anneal at optional operation 225, dopant concentration may be maintained in the silicon-containing material 315. The maintained dopant concentration may demonstrate that the dopant is bonded and incorporated within the silicon-containing material 315 and, therefore, may not migrate during further processing operations. For example, subsequent annealing at optional operation 225, the phosphorous content in the silicon-containing material may decrease by less than or about 1.0 at. %, and may decrease by less than or about 0.9 at. %, less than or about 0.8 at. %, less than or about 0.7 at. %, less than or about 0.6 at. %, less than or about 0.5 at. %, or less.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the material” includes reference to one or more materials and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing deposition precursors to a processing region of a semiconductor processing chamber, wherein a substrate is disposed within the processing region, and wherein the deposition precursors comprise a silicon-containing precursor;
providing a dopant precursor to the processing region of the semiconductor processing chamber, wherein the dopant precursor comprises a phosphorous-containing precursor;
generating plasma effluents of the deposition precursors and the dopant precursor;
and depositing a silicon-containing material on the substrate, wherein the silicon-containing material is characterized by a stress of greater than or about −50 MPa.

2. The semiconductor processing method of claim 1, wherein the silicon-containing precursor comprises tetraethyl orthosilicate (TEOS).

3. The semiconductor processing method of claim 1, wherein the deposition precursors further comprise an oxygen-containing precursor.

4. The semiconductor processing method of claim 3, wherein the oxygen-containing precursor comprises nitrous oxide (N₂O).

5. The semiconductor processing method of claim 1, wherein the plasma effluents of the deposition precursors and the dopant precursor are generated at a plasma power less than or about 2000 W.

6. The semiconductor processing method of claim 1, wherein the silicon-containing material is characterized by a leakage current of less than or about 5.0 E-08 A/cm² at 9 MV/cm.

7. The semiconductor processing method of claim 1, wherein the silicon-containing material is characterized by a breakdown voltage of greater than or about 6.0 MV/cm at 0.001 A/cm².

8. The semiconductor processing method of claim 1, wherein the silicon-containing material is characterized by a wet etch rate ratio (WERR) of greater than or about 2.0.

9. The semiconductor processing method of claim 1, further comprising:
annealing the silicon-containing material.

10. The semiconductor processing method of claim 1, wherein annealing the silicon-containing material comprises exposing the silicon-containing material to a temperature of greater than or about 600° C.

11. A semiconductor processing method comprising:
providing a silicon-containing precursor and an oxygen-containing precursor to a processing region of a semiconductor processing chamber, wherein a substrate is disposed within the processing region;
providing a dopant precursor to the processing region of the semiconductor processing chamber, wherein the dopant precursor comprises a phosphorous-containing precursor;
generating plasma effluents of the silicon-containing precursor, the oxygen-containing precursor, and the dopant precursor; and
depositing a silicon-containing material on the substrate, wherein the silicon-containing material is characterized by a stress of greater than or about −50 MPa, and wherein the silicon-containing material is characterized by a wet etch rate ratio (WERR) of greater than or about 2.0.

12. The semiconductor processing method of claim 11, wherein the dopant precursor comprises phosphine (PH₃).

13. The semiconductor processing method of claim 11, wherein a flow rate of the dopant precursor is less than or about 500 sccm.

14. The semiconductor processing method of claim 11, wherein the silicon-containing material is characterized by a phosphorous content of less than or about 5 at. %.

15. The semiconductor processing method of claim 11, wherein the silicon-containing material is deposited on a polysilicon material.

16. The semiconductor processing method of claim 11, further comprising:
annealing the silicon-containing material at a temperature of greater than or about 600° C. for greater than or about 5 minutes.

17. The semiconductor processing method of claim 16, wherein, subsequent annealing, a phosphorous content in the silicon-containing material decreases by less than or about 1.0 at. %.

18. A semiconductor processing method comprising:
providing deposition precursors to a processing region of a semiconductor processing chamber, wherein a substrate is disposed within the processing region;
providing a dopant precursor to the processing region of the semiconductor processing chamber, wherein the dopant precursor comprises a phosphorous-containing precursor;
generating plasma effluents of the deposition precursors and the dopant precursor; and
depositing a silicon-containing material on the substrate, wherein the silicon-containing material is characterized by a phosphorus content of less than or about 3 at. %, wherein the silicon-containing material is characterized by a stress of greater than or about −50 MPa, and wherein the silicon-containing material is characterized by a wet etch rate ratio (WERR) of greater than or about 2.0.

19. The semiconductor processing method of claim 18, wherein the silicon-containing material comprises phosphorous doped silicon oxide.

20. The semiconductor processing method of claim 18, wherein:
the silicon-containing material is characterized by a leakage current of less than or about 1.0 E-09 A/cm²; and
the silicon-containing material is characterized by a breakdown voltage of greater than or about 6.0 MV/cm at 0.001 A/cm².
